(19) United States
(12) Patent Application Publication
(10) Pub. No.: US 2026/0148945 A1
(43) Pub. Date: May 28, 2026

(54) MEASUREMENT SENSOR AND SUBSTRATE PROCESSING APPARATUS INCLUDING THE SAME

(71) Applicant: Samsung Electronics Co., Ltd., Suwon-si (KR)

(72) Inventors: Young YOON, Suwon-si (KR); Kyunghyun KIM, Suwon-si (KR); Sungwon CHO, Suwon-si (KR)

(73) Assignee: Samsung Electronics Co., Ltd., Suwon-si (KR)

(21) Appl. No.: 19/198,726

(22) Filed: May 5, 2025

(30) Foreign Application Priority Data
Nov. 28, 2024 (KR) 10-2024-0173660

(51) Int. Cl. H01J 37/32; H01L 21/67

(52) U.S. Cl. CPC H01J 37/32917; H01J 37/3244; H10P 72/0604; H01J 2237/24585

(57) ABSTRACT

Provided is a measurement sensor including a porous plate having a plurality of sensing holes, each sensing hole of the plurality of sensing holds including an opening on a surface of the porous plate, and a probe electrode under the opening of each sensing hole of the plurality of sensing holes, wherein an aspect ratio of each sensing hole of the plurality of sensing holes is defined as a width of the opening to a depth from the opening to the probe electrode, and the aspect ratios of the plurality of sensing holes may differ from each other.

### CROSS-REFERENCE TO RELATED APPLICATION(S)

This U.S. non-provisional application claims priority under 35 USC § 119 to Korean Patent Application No. 10-2024-0173660, filed on Nov. 28, 2024, in the Korean Intellectual Property Office, the disclosure of which is herein incorporated by reference in its entirety.

### BACKGROUND

Example embodiments relate to a measurement sensor and a substrate processing apparatus including the same, and more specifically, to a measurement sensor capable of measuring a plasma ion energy distribution and a substrate processing apparatus including the same.

Semiconductor devices can be manufactured by various manufacturing processes. In some of the manufacturing processes, plasma is utilized to perform manufacturing processes on a substrate. As the semiconductor devices become more highly integrated, the importance of measuring plasma ion energy distribution in a processing space is increasing. Accordingly, various studies on sensors capable of measuring the plasma ion energy distribution in the processing space are being conducted.

### SUMMARY

Some example embodiments may be directed to providing a measurement sensor capable of measuring a plasma ion energy distribution.

Some example embodiments may also be directed to providing a measurement sensor with improved accuracy in measuring the plasma ion energy distribution.

Some example embodiments may also be directed to providing a compact measurement sensor.

Some example embodiments may be directed to providing a measurement sensor in which a separate signal generator is omitted.

Some example embodiments may also be directed to providing a measurement sensor that operates in a wireless type.

Some example embodiments relate to a measurement sensor including a porous plate having a plurality of sensing holes, each sensing hole of the plurality of sensing holes including an opening on a surface of the porous plate, and a probe electrode under the opening of each sensing hole of the plurality of sensing holes, wherein an aspect ratio of each sensing hole of the plurality of sensing holes is defined as a width of the opening to a depth from the opening to the probe electrode, and the aspect ratios of the plurality of sensing holes may differ from each other.

Some example embodiments relate to a measurement sensor including a case, and a plurality of sensing ports on one surface of the case, wherein each sensing port of the plurality of sensing ports includes a porous plate having a plurality of sensing holes, each sensing hole of the plurality of sensing holes including an opening on a surface of the porous plate, and a probe electrode under the opening of each sensing hole of the plurality of sensing holes, an aspect ratio of each sensing hole of the plurality of sensing holes is defined as a width of the opening to a depth from the opening to the probe electrode, and the aspect ratios of the plurality of sensing holes differ from each other.

Some example embodiments relate to a substrate processing apparatus including a chamber defining a processing space, a shower head in the chamber, the shower head having a plurality of shower head holes connected to the processing space, a stage in the processing space, and a measurement sensor on the stage facing the processing space, wherein the measurement sensor includes a porous plate having a plurality of sensing holes, each sensing hole of the plurality of sensing holes including an opening on a surface of the porous plate, and a probe electrode under the opening of each sensing hole of the plurality of sensing holes, an aspect ratio of each sensing hole of the plurality of sensing holes is defined as a width of the opening to a depth from the opening to the probe electrode, and the aspect ratios of the plurality of sensing holes differ from each other.

Some example embodiments relate to a method of operation of a measurement sensor, the method including forming plasma in a processing space, filtering, by the measurement sensor, electrons and ions in the plasma, collecting the filtered ions in at least one sensing hole of a plurality of sensing holes, and measuring an ion energy distribution of the filtered ions incident into the at least one sensing hole.

In some example embodiments, the measuring the ion energy distribution includes electrically connecting a probe electrode within the at least one sensing hole to a reference electrode to cause a potential difference between the probe electrode and the reference electrode.

In some example embodiments, the measuring the ion energy distribution further includes calculating a current generated between the probe electrode and the reference electrode based on a resistor and a voltmeter electrically connected to the probe electrode and the reference electrode, and measuring the ion energy distribution based on the calculated current.

In some example embodiments, plasma electrons are filtered by a porous plate of the measurement sensor, the porous plate being a capillary plate.

### BRIEF DESCRIPTION OF DRAWINGS

FIG. 1 is a view showing a substrate processing apparatus according to some example embodiments.

FIG. 2 is a perspective view of a measurement sensor according to some example embodiments.

FIG. 3 is a perspective view of a sensing port according to some example embodiments.

FIG. 4 is a plan view of a sensing port according to some example embodiments.

FIG. 5 is a cross-sectional view taken along line I-I′ of FIG. 3.

FIG. 6 is a perspective view of a sensing port according to some example embodiments.

FIG. 7 is a cross-sectional view taken along line II-II′ of FIG. 6.

FIG. 8 is a cross-sectional view of a sensing port according to some example embodiments, and is a cross-sectional view corresponding to line II-II′ of FIG. 6.

FIG. 9 is a cross-sectional view of a sensing port according to some example embodiments, and is a cross-sectional view corresponding to line II-II′ of FIG. 6.

FIG. 10 is a cross-sectional view showing an operation method of a measurement sensor according to some example embodiments.

FIGS. 11 to 13 are graphs showing plasma ion energy distributions collected according to an operation of the measurement sensor according to some example embodiments.

### DETAILED DESCRIPTION

Hereafter, some example embodiments of the present disclosure will be clearly and thoroughly described with reference to the accompanying drawings.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof (e.g., structures, surfaces, directions, or the like), which may be referred to as being “perpendicular” or “parallel,” or the like with regard to other elements and/or properties thereof (e.g., structures, surfaces, directions, or the like) may be “perpendicular” or “parallel,” or the like or may be “substantially perpendicular” or “substantially parallel,” respectively, with regard to the other elements and/or properties element.

It will be understood that elements and/or properties thereof may be recited herein as being “similar,” “the same,” or “equal” as other elements, and it will be further understood that elements and/or properties thereof recited herein as being “similar” to, “the same” as, or “equal” to other elements may be “similar” to, “the same” as, or “equal” to the other elements and/or properties thereof. Elements and/or properties thereof that are “similar,” “the same,” or “equal” to other elements and/or properties thereof will be understood to include elements and/or properties thereof that are identical to, the same as, or equal to the other elements and/or properties thereof within manufacturing tolerances and/or material tolerances (e.g., ±10%). Elements and/or properties thereof that are similar, the same, and/or equal as other elements and/or properties thereof may be structurally the same or substantially the same, functionally the same or substantially the same, and/or compositionally the same or substantially the same.

When the terms “approximately,” “about” or “substantially” are used in this specification in connection with a numerical value, it is intended that the associated numerical value includes a manufacturing or operational tolerance (e.g., ±10%) around the stated numerical value. Moreover, when the words “approximately,” “about” and “substantially” are used in connection with geometric shapes, it is intended that precision of the geometric shape is not required but that latitude for the shape is within the scope of the disclosure. Further, regardless of whether numerical values or shapes are modified as “approximately,” “about” or “substantially,” it will be understood that these values and/or shapes should be construed as including a manufacturing or operational tolerance (e.g., ±10%) around the stated numerical values and/or shapes.

A used herein, the singular forms “a” and “an” are intended to include the plural forms as well, unless the context clearly indicates otherwise. Although the terms first, second, and the like may be used herein to describe various elements, components, steps and/or operations, these terms are only used to distinguish one element, component, step or operation from another element, component, step, or operation.

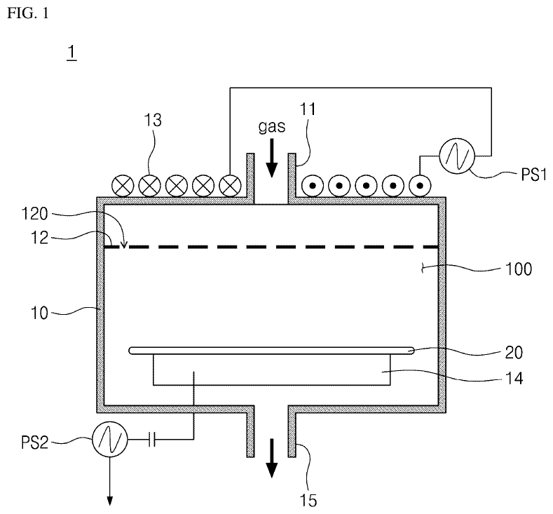

FIG. 1 is a view showing a substrate processing apparatus 1 according to some example embodiments.

Referring to FIG. 1, the substrate processing apparatus 1 may include a chamber 10 in which a processing space 100 is defined, a stage 14 provided in the processing space 100, and a measurement sensor 20 positionable on the stage 14. The substrate processing apparatus 1 may further include a shower head 12 provided in the chamber 10.

A substrate (not shown) may be processed in the processing space 100. For example, the substrate may be loaded onto the stage 14.

The chamber 10 may include a supply pipe 11 through which plasma gas is supplied. The supply pipe 11 may be provided at an upper portion of the chamber 10. The chamber 10 may include an outlet 15 through which a substance in the processing space 100 is discharged. The outlet 15 may be provided at a lower portion of the chamber 10. A fluid in the processing space 100 may be discharged to the outside of the chamber 10 through the outlet 15. For example, a residual substance after a plasma etching process is performed may be discharged to the outside of the chamber 10 through the outlet 15.

The measurement sensor 20 may be loaded onto the stage 14. The stage 14 may be an electrostatic chuck that fixes the loaded substrate. The stage 14 may also fix the measurement sensor 20. In some example embodiments, the stage 14 may rotate the loaded substrate. The substrate or the measurement sensor 20 loaded on the stage 14 may face the processing space 100. For example, the substrate loaded on the stage 14 may be exposed to the processing space 100, and a processing process of the substrate may be performed.

The shower head 12 may be provided above the processing space 100. The shower head 12 may include a plurality of shower head holes 120 connected to the processing space 100. The shower head 12 may distribute (or uniformly distribute) the supplied plasma gas in the processing space 100.

In some example embodiments, the substrate processing apparatus 1 may further include a coil 13 coupled to the chamber 10. For example, the coil 13 may be a helical coil. The wound coil 13 may be provided on an upper surface of the chamber 10.

The coil 13 may be connected to a first power supply PS1. The stage 14 may be connected to a second power supply PS2. The first power supply PS1 and the second power supply PS2 may generate high-frequency power. For example, the first power supply PS1 and the second power supply PS2 may generate radio frequency (RF) power. Therefore, when the first power supply PS1 and the second power supply PS2 apply the high-frequency power to the coil 13 and the stage 14, respectively, plasma may be generated in the chamber 10.

The measurement sensor 20 may be disposed in the processing space 100. The measurement sensor 20 may be loaded onto the stage 14. The measurement sensor 20 may be a mobile measurement sensor that can be drawn into or drawn out from the chamber 10. For example, the measurement sensor 20 may be drawn into the chamber 10 as needed to measure a plasma ion energy distribution, and drawn out from the chamber 10 after the measurement. In some example embodiments, the measurement sensor 20 may be a wireless-type measurement sensor that operates without a separate wired connection.

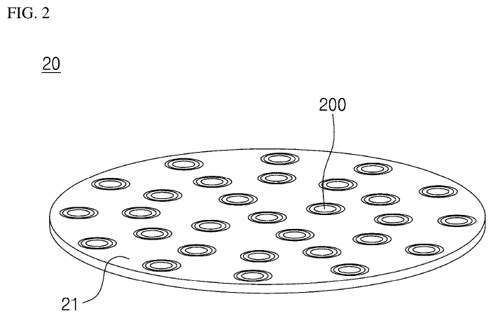

FIG. 2 is a perspective view of the measurement sensor 20 according to some example embodiments.

Referring to FIG. 2, the measurement sensor 20 may include a case 21 defining its exterior. The case 21 may be provided in a shape of the substrate. In some example embodiments, a shape and a size of the case 21 may be the same as or similar to a shape and a size of the substrate. For example, the case 21 may be provided in a shape of a thin disc (or in a shape of a disc). The case 21 may include an internal space in which components of the measurement sensor 20 are accommodated. The case 21 may include silicon (Si), germanium (Ge), silicon-germanium (Si-Ge), or carbon, but example embodiments are not limited thereto.

The measurement sensor 20 may include a plurality of sensing ports 200 provided on one surface (or on a first surface) of the case 21. The case 21 may be loaded onto the stage 14 so that one surface of the case faces the processing space 100. One surface (or a first surface) of the case 21 may face the processing space 100, and the other surface (or a second surface) of the case 21 may face the stage 14. Therefore, one surface of the case 21 may be exposed to the plasma in the processing space 100.

The plurality of sensing ports 200 may collect plasma ions. For example, the plurality of sensing ports 200 may be exposed to the plasma ions. The plurality of sensing ports 200 may be radially arranged on one surface of the case 21. Alternatively or additionally, in some example embodiments, the plurality of sensing ports 200 may be randomly arranged on one surface of the case 21.

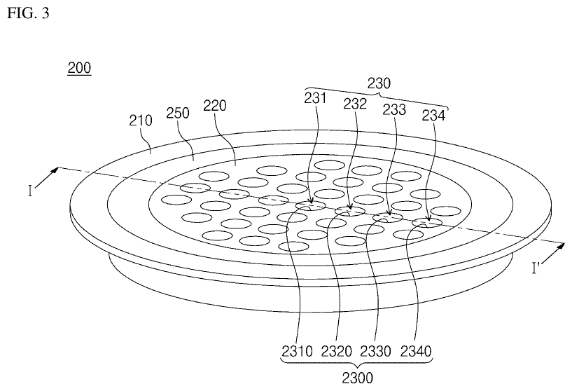

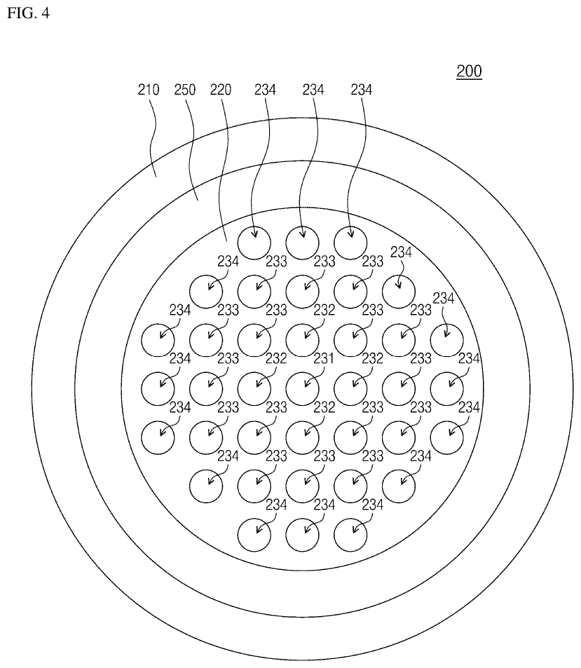

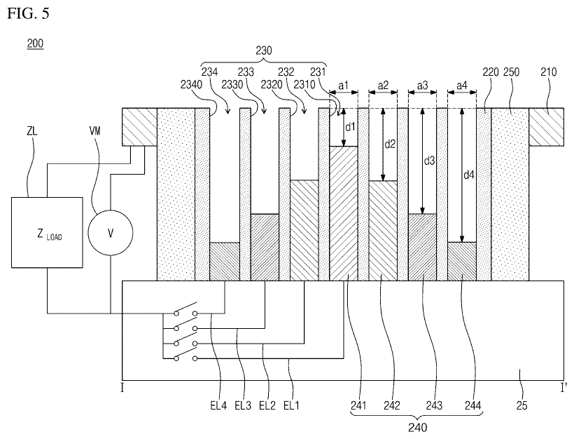

FIG. 3 is a perspective view of the sensing port 200 according to some example embodiments. FIG. 4 is a plan view of the sensing port 200 according to some example embodiments. FIG. 5 is a cross-sectional view taken along line I-I′ of FIG. 3.

Referring to FIGS. 3 to 5, each of the plurality of sensing ports 200 may include a porous plate 220 having a plurality of sensing holes 230, a probe electrode 240 provided in each of the sensing holes 230, and a reference electrode 210 electrically connected to the probe electrode 240.

The porous plate 220 may be provided in a shape of a porous thin plate (or a porous plate). Each of the plurality of sensing holes 230 may be a capillary passing through the porous plate 220. Each of the plurality of the sensing holes 230 may extend perpendicular to the porous plate 220. In some example embodiments, each of the plurality of the sensing holes 230 may extend in a thickness direction of the porous plate 220. For example, the porous plate 220 may be a capillary plate having multiple capillaries. Therefore, the porous plate 220 may minimize (or reduce) the phenomenon in which plasma electrons are collected on the probe electrodes 240.

Each of the sensing holes 230 may include an opening 2300 provided on one surface of the porous plate 220. One surface of the porous plate 220 may face the processing space 100 in the chamber 10. The probe electrodes 240 may collect the plasma ions through the openings 2300.

Each of the probe electrodes 240 may be provided under the opening 2300 of each of the sensing holes 230. In some example embodiments, each of the probe electrodes 240 may also be provided in the each of the sensing holes 230.

The probe electrodes 240 may vertically extend. For example, the probe electrodes 240 may extend in a thickness direction of the case 21. Each of one ends (or a first end) of the probe electrodes 240 may face the opening 2300. The one end of each of the probe electrodes 240 toward the opening 2300 may be referred to as tip. The probe electrode 240 may include silicon, germanium, silicon-germanium, or carbon, but example embodiments are not limited thereto.

In some example embodiments, heights of the probe electrodes 240 may differ from each other. For example, the tips of the probe electrodes 240 may be provided at different levels.

Aspect ratios of the sensing holes 230 may differ from each other. In one sensing hole 230 and the probe electrode 240 disposed inside the one sensing hole 230, the aspect ratio may be defined as a width of the opening 2300 to a depth from the opening 2300 to the probe electrode 240. For example, the depth from the opening 2300 to the probe electrode 240 may be defined as a distance between a level of the opening 2300 and the level of the tip of the probe electrode 240. The level of the opening 2300 may be a level of one surface of the porous plate 220 on which the opening 2300 is provided. Additionally or alternatively, the width of the opening 2300 may refer to a diameter of the opening 2300.

For example, the sensing holes 230 may include a first sensing hole 231, a second sensing hole 232, a third sensing hole 233, and a fourth sensing hole 234, and the aspect ratios of the first to fourth sensing holes 231, 232, 233, and 234 may differ from each other. The first sensing hole 231 may have a first opening 2310, the second sensing hole 232 may have a second opening 2320, the third sensing hole 233 may have a third opening 2330, and the fourth sensing hole 234 may have a fourth opening 2340. A first probe electrode 241 may be provided under the first opening 2310, a second probe electrode 242 may be provided under the second opening 2320, a third probe electrode 243 may be provided under the third opening 2330, and a fourth probe electrode 244 may be provided under the fourth opening 2340. A height of the first probe electrode 241 may be larger than a height of the second probe electrode 242, the height of the second probe electrode 242 may be larger than a height of the third probe electrode 243, and the height of the third probe electrode 243 may be larger than a height of the fourth probe electrode 244.

A first aspect ratio of the first sensing hole 231 may be defined as a first width a1 of the first opening 2310 to a first depth d1 from the first opening 2310 to the first probe electrode 241. Additionally or alternatively, a second aspect ratio of the second sensing hole 232 may be defined as a second width a2 of the second opening 2320 to a second depth d2 from the second opening 2320 to the second probe electrode 242. Additionally or alternatively, a third aspect ratio of the third sensing hole 233 may be defined as a third width a3 of the third opening 2330 to a third depth d3 from the third opening 2330 to the third probe electrode 243. Additionally or alternatively, a fourth aspect ratio of the fourth sensing hole 234 may be defined as a fourth width a4 of the fourth opening 2340 to a fourth depth d4 from the fourth opening 2340 to the fourth probe electrode 244. In some example embodiments, the aspect ratios of the sensing holes 230 may increase in the order of the first aspect ratio, the second aspect ratio, the third aspect ratio, and the fourth aspect ratio. In some example embodiments, the second aspect ratio may be larger than the first aspect ratio, the third aspect ratio may be larger than the second aspect ratio, and the fourth aspect ratio may be larger than the third aspect ratio. For example, the first aspect ratio may be d1/a1, the second aspect ratio may be d2/a2, the third aspect ratio may be d3/a3, and the fourth aspect ratio may be d4/a4.

The sensing port 200 of some example embodiments shows the first sensing holes 231 to the fourth sensing holes 234 having four different aspect ratios, but this is merely an example, and example embodiments are not limited thereto. For example, the aspect ratios of the sensing holes 230 provided in the porous plate 220 may be provided in a more variety.

The aspect ratios of the sensing holes 230 may increase toward an edge of the porous plate 220. Conversely, the aspect ratios of the sensing holes 230 may decrease toward a center of the porous plate 220. For example, in a plan view, the first sensing hole 231 having the first aspect ratio may be located at the center of the porous plate 220, the second sensing holes 232 having the second aspect ratio larger than the first aspect ratio may be arranged to surround the first sensing hole 231, the third sensing holes 233 having the third aspect ratio larger than the second aspect ratio may be arranged to surround the second sensing holes 232, and the fourth sensing holes 234 having the fourth aspect ratio larger than the third aspect ratio may be arranged to surround the third sensing holes 233.

Alternatively or additionally, in some example embodiments, the sensing holes 230 having different aspect ratios may be randomly arranged on the porous plate 220.

In some example embodiments, a proportion of sensing holes 230 having a larger aspect ratio of one surface of the porous plate 220 may be greater than a proportion of sensing holes 230 having a smaller aspect ratio of one surface of the porous plate 220. In other words, a total opening area of sensing holes 230 having the larger aspect ratio of one surface of the porous plate 220 may be larger than a total opening area of sensing holes 230 having the smaller aspect ratio of one surface of the porous plate 220. For example, a total opening area of the second sensing holes 232 may be larger than a total opening area of the first sensing hole 231, and a total opening area of the third sensing holes 233 may be larger than the total opening area of the second sensing holes 232.

The porous plate 220 may include an insulating material. For example, each of the probe electrodes 240 may be provided in each of the sensing holes 230, and the porous plate 220 may be provided even between the probe electrodes 240. Therefore, the porous plate 220 may electrically insulate the probe electrodes 240 from each other.

The reference electrode 210 may be electrically connected to the probe electrodes 240. The reference electrode 210 may be disposed at one side of the porous plate 220. The reference electrode 210 may be spaced apart from the porous plate 220. The reference electrode 210 may be exposed through one surface of the case 21. Therefore, the reference electrode 210 may collect the plasma ions and the electrons.

The sensing port 200 may further include an insulating plate 250 provided between the reference electrode 210 and the porous plate 220. The insulating plate 250 may allow the reference electrode 210 to be structurally spaced apart from the porous plate 220. The insulating plate 250 may allow the reference electrode 210 to be electrically insulated from the porous plate 220.

The sensing port 200 may include a measurement circuit that electrically connects the reference electrode 210 to the probe electrodes 240. The measurement circuit may include a resistor ZL connected to the reference electrode 210. For example, the resistor ZL may have a variable impedance.

In some example embodiments, the measurement circuit may further include a voltmeter VM. The resistor ZL and the voltmeter VM may be connected in parallel with each other.

Alternatively or additionally, in some example embodiments, the measurement circuit may further include an ammeter (not shown). The resistor ZL and the ammeter (not shown) may be connected in series.

The probe electrodes 240 may be connected to the resistor ZL. The probe electrodes 240 may be connected in parallel to each other. A switch may be provided on each of lines connecting the probe electrodes 240 in parallel. Therefore, at least one of the probe electrodes 240 may be selectively connected to the resistor ZL.

In some example embodiments, the measurement circuit may include the resistor ZL connected to each of the probe electrodes 240. For example, the measurement circuit may include a plurality of resistors ZL connected to the probe electrodes 240. Each of the plurality of resistors ZL may be connected to the reference electrode 210 and each of the probe electrodes 240.

The case 21 may include a base 25. The base 25 may be a portion of the case 21. For example, the base 25 may be a lower portion of the case 21. The porous plate 220 may be provided on the base 25. The insulating plate 250 may be provided on the base 25. The probe electrodes 240 may be provided on the base 25. The base 25 may include silicon, germanium, silicon-germanium, or carbon, but example embodiments are not limited thereto.

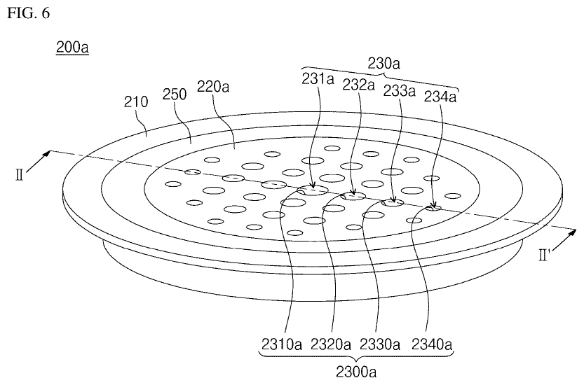

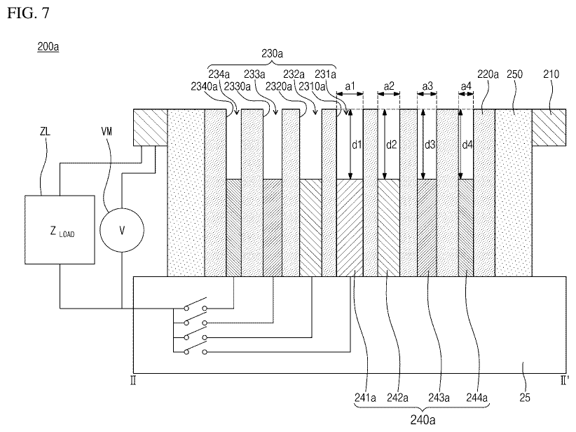

FIG. 6 is a perspective view of a sensing port 200a according to some example embodiments. FIG. 7 is a cross-sectional view taken along line II-II′ of FIG. 6.

Most of components and materials forming the components, which constitute the sensing port 200a described below are substantially the same as or similar to the components of the sensing port 200 described above in FIGS. 1 to 5. Therefore, for the convenience of explanation, differences from the above-described sensing port 200 will be mainly described.

Referring to FIGS. 6 and 7, in some example embodiments, a porous plate 220a may include sensing holes 230a having different widths. For example, openings 2300a provided on one surface of the porous plate 220a may have different widths. In some example embodiments, the width of the opening 2300a may refer to a diameter of the opening 2300a. For example, a first sensing hole 231a may include a first opening 2310a having a first width a1, a second sensing hole 232a may include a second opening 2320a having a second width a2, a third sensing hole 233a may include a third opening 2330a having a third width a3, and a fourth sensing hole 234a may include a fourth opening 2340a having a fourth width a4. In some example embodiments, the first width a1 may be larger than the second width a2, the second width a2 may be larger than the third width a3, and the third width a3 may be larger than the fourth width a4. For example, the widths of the sensing holes 230a may decrease from the first sensing hole 231a to the fourth sensing hole 234a.

In some example embodiments, the widths of the sensing holes 230a may decrease toward an edge of the porous plate 220a. Conversely, the widths of the sensing holes 230a may increase toward a center of the porous plate 220a.

In some example embodiments, probe electrodes 240a provided under the openings 2300a with different widths may have substantially the same height. For example, tips of the probe electrodes 240a may be provided at substantially the same level.

Aspect ratios of the sensing holes 230a may differ from each other. For example, the sensing holes 230a may include the first sensing hole 231a, the second sensing hole 232a, the third sensing hole 233a, and the fourth sensing hole 234a, and the aspect ratios of the first to fourth sensing holes 231a, 232a, 233a, and 234a may differ from each other. The first sensing hole 231a may have the first opening 2310a, the second sensing hole 232a may have the second opening 2320a, the third sensing hole 233a may have the third opening 2330a, and the fourth sensing hole 234a may have the fourth opening 2340a. First to fourth probe electrodes 241a, 242a, 243a, and 244a having substantially the same height may be provided in the first to fourth sensing holes 231a, 232a, 233a, and 234a.

A first aspect ratio of the first sensing hole 231a may be defined as the first width a1 of the first opening 2310a to a first depth d1 from the first opening 2310a to the first probe electrode 241a. Alternatively or additionally, a second aspect ratio of the second sensing hole 232a may be defined as the second width a2 of the second opening 2320a to a second depth d2 from the second opening 2320a to the second probe electrode 242a. Alternatively or additionally, a third aspect ratio of the third sensing hole 233a may be defined as the third width a3 of the third opening 2330a to a third depth d3 from the third opening 2330a to the third probe electrode 243a. Alternatively or additionally, a fourth aspect ratio of the fourth sensing hole 234a may be defined as the fourth width a4 of the fourth opening 2340a to a fourth depth d4 from the fourth opening 2340a to the fourth probe electrode 244a. In some example embodiments, since the heights of the first to fourth probe electrodes 241a, 242a, 243a, and 244a are substantially the same but the widths a1, a2, a3, and a4 of the first to fourth openings 2310a, 2320a, 2330a, and 2340a differ from each other, the aspect ratios of the sensing holes 230a may increase in the order of the first aspect ratio, the second aspect ratio, the third aspect ratio, and the fourth aspect ratio. In some example embodiments, the second aspect ratio may be larger than the first aspect ratio, the third aspect ratio may be larger than the second aspect ratio, and the fourth aspect ratio may be larger than the third aspect ratio. For example, the first aspect ratio may be d1/a1, the second aspect ratio may be d2/a2, the third aspect ratio may be d3/a3, and the fourth aspect ratio may be d4/a4.

Accordingly, the sensing holes 230a may have different aspect ratios due to differences in the widths of the openings 2300a.

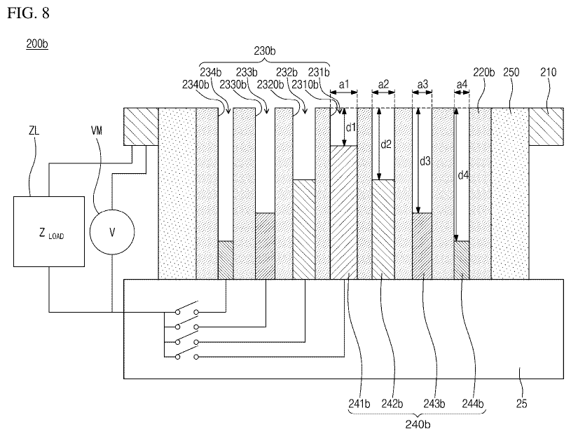

FIG. 8 is a cross-sectional view of a sensing port 200b according to some example embodiments, and is a cross-sectional view corresponding to line II-II′ of FIG. 6.

Most components and materials forming the components, which constitute the sensing port 200b described below are substantially the same as or similar to the components of the sensing ports 200 and 200a described above in FIGS. 1 to 7. Therefore, for convenience of explanation, differences from the above-described sensing ports 200 and 200a will be mainly described.

Referring to FIG. 8, in some example embodiments, probe electrodes 240b provided in the sensing holes 230b having different widths may have different heights.

For example, the sensing holes 230b may include a first sensing hole 231b, a second sensing hole 232b, a third sensing hole 233b, and a fourth sensing hole 234b, and aspect ratios of the first to fourth sensing holes 231b, 232b, 233b, and 234b may differ from each other.

The first sensing hole 231b may include a first opening 2310b having a first width a1, the second sensing hole 232b may include a second opening 2320b having a second width a2, the third sensing hole 233b may include a third opening 2330b having a third width a3, and the fourth sensing hole 234b may include a fourth opening 2340b having a fourth width a4.

A first probe electrode 241b may be provided under the first opening 2310b, a second probe electrode 242b may be provided under the second opening 2320b, a third probe electrode 243b may be provided under the third opening 2330b, and a fourth probe electrode 244b may be provided under the fourth opening 2340b. A height of the first probe electrode 241b may be larger than a height of the second probe electrode 242b, the height of the second probe electrode 242b may be larger than a height of the third probe electrode 243b, and the height of the third probe electrode 243b may be larger than a height of the fourth probe electrode 244b.

A first aspect ratio of the first sensing hole 231b may be defined as the first width a1 of the first opening 2310b to a first depth d1 from the first opening 2310b to the first probe electrode 241b. Alternatively or additionally, a second aspect ratio of the second sensing hole 232b may be defined as the second width a2 of the second opening 2320b to a second depth d2 from the second opening 2320b to the second probe electrode 242b. Alternatively or additionally, a third aspect ratio of the third sensing hole 233b may be defined as the third width a3 of the third opening 2330b to a third depth d3 from the third opening 2330b to the third probe electrode 243b. Alternatively or additionally, a fourth aspect ratio of the fourth sensing hole 234b may be defined as the fourth width a4 of the fourth opening 2340b to a fourth depth d4 from the fourth opening 2340b to the fourth probe electrode 244b.

Accordingly, a spectrum of aspect ratios may be further expanded.

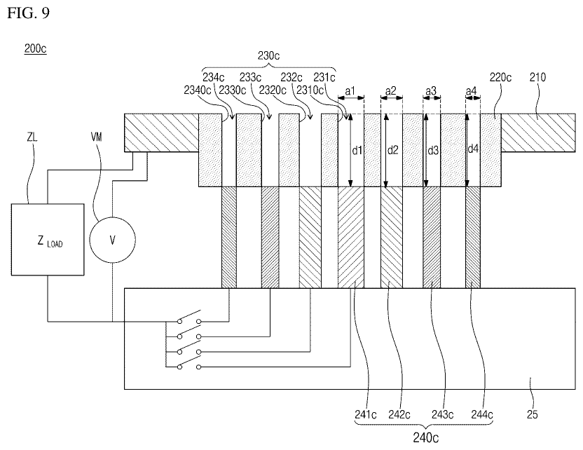

FIG. 9 is a cross-sectional view of a sensing port 200c according to some example embodiments, and is a cross-sectional view corresponding to line II-II′ of FIG. 6.

Most components and materials forming the components, which constitute the sensing port 200c described below are substantially the same as or similar to the components of the sensing ports 200, 200a, and 200b described above in FIGS. 1 to 8. Therefore, for the convenience of explanation, differences from the above-described sensing ports 200, 200a, and 200b will be mainly described.

Referring to FIG. 9, in some example embodiments, probe electrodes 240c may also be provided under a porous plate 220c. In some example embodiments, each of the probe electrodes 240c may be provided under each of a plurality of sensing holes 230c provided in the porous plate 220c. For example, a first probe electrode 241c may be provided under a first sensing hole 231c, a second probe electrode 242c may be provided under a second sensing hole 232c, a third probe electrode 243c may be provided under a third sensing hole 233c, and a fourth probe electrode 244c may be provided under a fourth sensing hole 234c. In some example embodiments, the probe electrodes 240c may be spaced apart from the porous plate 220c.

In some example embodiments, the probe electrodes 240c provided under openings 2300c with different widths may have substantially the same height. For example, tips of the probe electrodes 240c may be provided at substantially the same level.

The first sensing hole 231c may include a first opening 2310c having a first width a1, the second sensing hole 232c may include a second opening 2320c having a second width a2, the third sensing hole 233c may include a third opening 2330c having a third width a3, and the fourth sensing hole 234c may include a fourth opening 2340c having a fourth width a4. In some example embodiments, the first width a1 may be larger than the second width a2, the second width a2 may be larger than the third width a3, and the third width a3 may be larger than the fourth width a4. For example, widths of the sensing holes 230c may decrease from the first sensing hole 231c to the fourth sensing hole 234c.

In some example embodiments, the widths of the sensing holes 230c may decrease toward an edge of the porous plate 220c. Conversely, the widths of the sensing holes 230c may increase toward a center of the porous plate 220c.

Accordingly, the sensing holes 230c with different aspect ratios may be provided.

Each of the probe electrodes 240c may be vertically aligned with each of the sensing holes 230c. In a plan view, each of the probe electrodes 240c may overlap each of the sensing holes 230c.

The probe electrodes 240c may be spaced apart from each other. Empty spaces may be defined between the probe electrodes 240c.

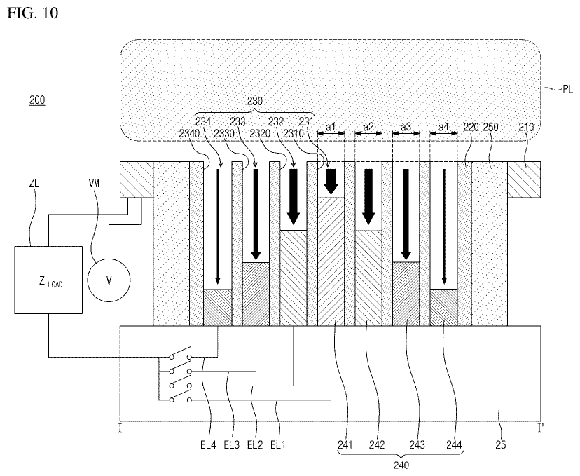

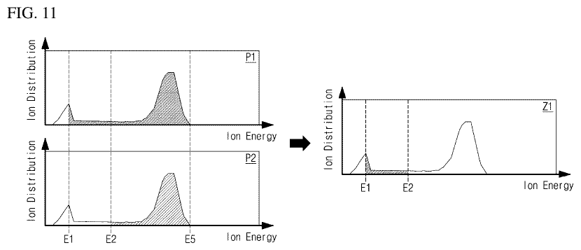

FIG. 10 is a cross-sectional view showing an operation method of the measurement sensor 20 according to some example embodiments. FIGS. 11 to 13 are graphs showing plasma ion energy distributions collected according to an operation of the measurement sensor 20 according to some example embodiments.

Referring to FIGS. 10 and 11, plasma may be formed in the processing space 100. The measurement sensor 20 may be exposed to the plasma in the processing space 100. The measurement sensor 20 may collect electrons and ions in the plasma. Therefore, the measurement sensor may obtain data of a plasma ion energy distribution.

The porous plate 220 may filter plasma electrons. For example, the porous plate 220 may be a capillary plate that filters the plasma electrons. Therefore, the plasma electrons may not penetrate into the sensing holes 230 provided in the porous plate 220. This may be caused by characteristics of the plasma electrons and a structure of the porous plate 220.

Accordingly, the plasma electrons may be filtered by the porous plate 220, and plasma ions may be incident into the sensing holes 230 provided in the porous plate 220 (e.g., plasma ions may be directed to or may enter into the sensing holes 230 provided in the porous plate 220 such that the plasma ions may move towards and/or interact with the sensing holes 230).

Incident distances of the plasma ions may be related to energies of the plasma ions. For example, the plasma ions with higher energy may more deeply penetrate the sensing hole 230, and the plasma ions with lower energy may have difficulty in deeply penetrating the sensing hole 230.

Alternatively or additionally, the incident distance of the plasma ions may be related to an aspect ratio of each of the sensing holes 230. For example, when the aspect ratio of the sensing hole 230 is small, the plasma ions may penetrate deeply into the sensing hole 230, but when the aspect ratio of the sensing hole 230 is large, the plasma ions may have difficulty in deeply penetrating the sensing hole 230. Accordingly, the plasma ions having high energy may penetrate the sensing hole 230 with a large aspect ratio, but the plasma ions having low energy may have difficulty in penetrating the sensing hole 230 with the large aspect ratio.

For example, as described above in FIG. 5, the first to fourth widths a1, a2, a3, and a4 of the first to fourth sensing holes 231, 232, 233, and 234 may be the same. However, heights of the first to fourth probe electrodes 241, 242, 243, and 244 respectively provided in the first to fourth sensing holes 231, 232, 233, and 234 may differ. For example, the height of the first probe electrode 241 may be larger than the height of the second probe electrode 242, the height of the second probe electrode 242 may be larger than the height of the third probe electrode 243, and the height of the third probe electrode 243 may be larger than the height of the fourth probe electrode 244. Accordingly, an aspect ratio of the second sensing hole 232 may be larger than an aspect ratio of the first sensing hole 231, an aspect ratio of the third sensing hole 233 may be larger than the aspect ratio of the second sensing hole 232, and an aspect ratio of the fourth sensing hole 234 may be larger than the aspect ratio of the third sensing hole 233.

Accordingly, ions belonging to an energy band from low energy to high energy may be evenly incident into the first sensing hole 231 with the small aspect ratio. Since the aspect ratio of the second sensing hole 232 is larger than the aspect ratio of the first sensing hole 231, a smaller amount of ions than an amount of ions that is incident into the first sensing hole 231 may be incident into the second sensing hole 232 (e.g., an amount of ions incident into the second hole 232 may be smaller than an amount of ions incident into the first sensing hole 231). Alternatively or additionally, since the aspect ratio of the third sensing hole 233 is larger than the aspect ratio of the second sensing hole 232, a smaller amount of ions than an amount of ions that is incident into the second sensing hole 232 may be incident into the third sensing hole 233 (e.g., an amount of ions incident into the third hole 233 may be smaller than an amount of ions incident into the second sensing hole 232). Alternatively or additionally, since the aspect ratio of the fourth sensing hole 234 is larger than the aspect ratio of the third sensing hole 233, a smaller amount of ions than an amount of ions that is incident into the third sensing hole 233 may be incident into the fourth sensing hole 234 (e.g., an amount of ions incident into the fourth hole 234 may be smaller than an amount of ions incident into the third sensing hole 233).

As the aspect ratio of the sensing hole 230 increases, the minimum required energy of ions (or a threshold of energy of ions) to be collected at the probe electrode 240 in the sensing hole 230 may increase. For example, as the aspect ratio of the sensing hole 230 increases, the average energy of plasma ions collected by the probe electrode 240 provided inside the sensing hole 230 may increase.

The measurement sensor 20 may measure a first ion energy distribution P1 of plasma ions incident on the first probe electrode 241 by closing the switch of a line EL1 to which the first probe electrode 241 is connected. In some example embodiments, the switches of lines EL2, EL3, and EL4 to which the second to fourth probe electrodes 242, 243, and 244 are connected may be open.

In some example embodiments, when the first probe electrode 241 is electrically connected to the reference electrode 210, a potential difference may occur between the first probe electrode 241 and the reference electrode 210 due to the plasma ions incident on the first probe electrode 241. As a result, a current is generated between the first probe electrode 241 and the reference electrode 210, and the measurement sensor 20 may calculate a current value based on the resistor ZL and the voltmeter VM. Consequently, the measurement sensor 20 may obtain (or determine) the first ion energy distribution P1 between a first energy E1 and a fifth energy E5 based on the calculated current value.

The measurement sensor 20 may measure a second ion energy distribution P2 of plasma ions incident on the second probe electrode 242 by closing the switch of the line EL2 to which the second probe electrode 242 is connected. In some example embodiments, the switches of the lines EL1, EL3, and EL4 to which the first probe electrode 241, the third probe electrode 243, and the fourth probe electrode 244 are connected may be open.

In some example embodiments, when the second probe electrode 242 is electrically connected to the reference electrode 210, a potential difference may occur between the second probe electrode 242 and the reference electrode 210 due to the plasma ions incident on the second probe electrode 242. As a result, a current is generated between the second probe electrode 242 and the reference electrode 210, and the measurement sensor 20 may calculate the current value based on the resistor ZL and the voltmeter VM. Therefore, the measurement sensor 20 may obtain the second ion energy distribution P2 between a second energy E2 and the fifth energy E5.

Furthermore, the measurement sensor 20 may obtain an ion energy distribution Z1 between the first energy E1 and the second energy E2 based on the difference between the first ion energy distribution P1 and the second ion energy distribution P2.

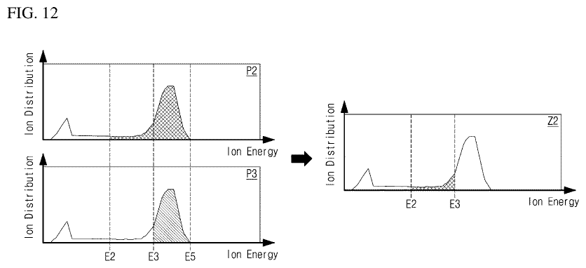

Referring to FIGS. 10 and 12, the measurement sensor 20 may measure a third ion energy distribution P3 of plasma ions incident on the third probe electrode 243 by closing the switch of the line EL3 to which the third probe electrode 243 is connected. In some example embodiments, the switches of the lines EL1, EL2, and EL4 to which the first probe electrode 241, the second probe electrode 242, and the fourth probe electrode 244 are connected may be open.

In some example embodiments, when the third probe electrode 243 is electrically connected to the reference electrode 210, a potential difference may occur between the third probe electrode 243 and the reference electrode 210 due to the plasma ions incident on the third probe electrode 243. As a result, a current is generated between the third probe electrode 243 and the reference electrode 210, and the measurement sensor 20 may calculate the current value based on the resistor ZL and the voltmeter VM. Therefore, the measurement sensor 20 may obtain the third ion energy distribution P3 between a third energy E3 and the fifth energy E5.

Furthermore, the measurement sensor 20 may obtain an ion energy distribution Z2 between the second energy E2 and the third energy E3 based on the difference between the second ion energy distribution P2 and the third ion energy distribution P3.

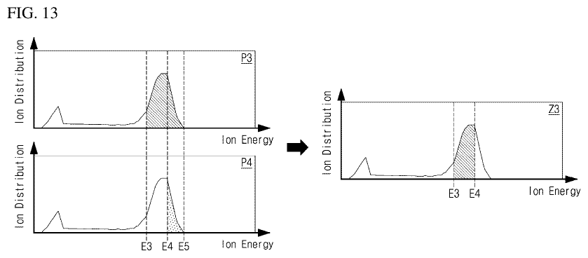

Referring to FIG. 10 and FIG. 13, the measurement sensor 20 may measure a fourth ion energy distribution P4 of plasma ions incident on the fourth probe electrode 244 by closing the switch of the line EL 4 to which the fourth probe electrode 244 is connected. In some example embodiments, the switches of the lines EL1, EL2, and EL3 to which the first to third probe electrodes 241, 242, and 243 are connected may be open.

In some example embodiments, when the fourth probe electrode 244 is electrically connected to the reference electrode 210, a potential difference may occur between the fourth probe electrode 244 and the reference electrode 210 due to the plasma ions incident on the fourth probe electrode 244. As a result, a current is generated between the fourth probe electrode 244 and the reference electrode 210, and the measurement sensor 20 may calculate the current value based on the resistor ZL and the voltmeter VM. Therefore, the measurement sensor 20 may obtain the fourth ion energy distribution P4 between a fourth energy E4 and the fifth energy E5.

Furthermore, the measurement sensor 20 may obtain an ion energy distribution Z3 between the third energy E3 and the fourth energy E4 based on the difference between the third ion energy distribution P3 and the fourth ion energy distribution P4.

According to some example embodiments, a porous plate having a plurality of sensing holes can filter plasma electrons, thereby minimizing (or reducing) the phenomenon of the plasma electrons approaching probe electrodes. Accordingly, a measurement sensor with improved accuracy in measuring a plasma ion energy distribution can be provided.

Alternatively or additionally, according to some example embodiments, due to the plurality of sensing holes with different aspect ratios, the measurement sensor can measure plasma ions by an energy band. Accordingly, the measurement sensor with improved measurement accuracy of ion energy distribution can be provided.

Alternatively or additionally, according to some example embodiments, the measurement sensor can obtain distribution data according to the band of plasma ion energy through a current between a reference electrode exposed to plasma and probe electrodes exposed to the plasma ions.

Alternatively or additionally, according to some example embodiments, since the measurement sensor includes its own reference electrode, it is possible to obtain the plasma ion energy distribution without a separate signal generator. Therefore, a compact and wireless-type measurement sensor can be used to implement a process environment similar to a process environment in which an actual substrate is processed.

Alternatively or additionally, according to some example embodiments, a total opening area of the sensing holes with a large aspect ratio can be made larger than the total opening area of the sensing holes with a small aspect ratio, thereby further improving the measurement accuracy of plasma ion energy analysis by the measurement sensor. For example, since a small number of ions having relatively large energy are collected in the probe electrodes in the sensing holes with the large aspect ratio, the reliability of the collected data can be supplemented by increasing an opening area of the sensing holes with the large aspect ratio and the number of probe electrodes therein.

Alternatively or additionally, according to some example embodiments, the probe electrodes that detect the plasma ions may include silicon, germanium, silicon-germanium, or carbon, (but are not limited thereto) so that the measurement sensor can obtain the plasma ion energy distribution approximate to the plasma ion energy distribution during an actual substrate processing process.

Alternatively or additionally, according to some example embodiments, the probe electrodes can be electrically insulated from each other by being spaced apart, or a porous plate including an insulating material between the probe electrodes can electrically insulate the probe electrodes from each other. Accordingly, the measurement accuracy of the plasma ion energy distribution of the measurement sensor can be improved.

Alternatively or additionally, according to some example embodiments, due to the plurality of sensing ports that are radially arranged, the measurement sensor can obtain data of the plasma ion energy distribution according to each horizontal direction position.

The above-described contents include some example embodiments for implementing the present inventive concepts. In addition to the above-described embodiments, the present inventive concepts also include example embodiments that can be simply designed around or easily changed. In addition, the present inventive concepts also include technologies that can be implemented by being easily modified using the example embodiments. Therefore, the scope of the present inventive concepts should not be limited to the above-described example embodiments, but should be determined not only by the appended claims but also by the equivalents of the claims of the present inventive concepts.

What is claimed is:

1. A measurement sensor comprising:
a porous plate having a plurality of sensing holes, each sensing hole of the plurality of sensing holes including an opening on a surface of the porous plate; and
a probe electrode under the opening of each sensing hole of the plurality of sensing holes, wherein
an aspect ratio of each sensing hole of the plurality of sensing holes is defined as a width of the opening to a depth from the opening to the probe electrode, and
the aspect ratios of the plurality of sensing holes differ from each other.

2. The measurement sensor of claim 1, wherein
first ends of the probe electrodes toward the openings are at different levels.

3. The measurement sensor of claim 1, wherein
the probe electrodes in the plurality of sensing holes have different heights.

4. The measurement sensor of claim 1, wherein
the openings of the plurality of sensing holes have different widths.

5. The measurement sensor of claim 4, wherein
first ends of the probe electrodes toward the openings are at the same level.

6. The measurement sensor of claim 1, wherein
the plurality of sensing holes include,
first sensing holes having a first aspect ratio; and
second sensing holes having a second aspect ratio larger than the first aspect ratio,
each of the first sensing holes includes a first opening on the surface of the porous plate,
each of the second sensing holes includes a second opening on the surface of the porous plate, and
a total area of the second openings on the porous plate is larger than a total area of the first openings.

7. The measurement sensor of claim 6, wherein
the plurality of sensing holes further include third sensing holes having a third aspect ratio larger than the second aspect ratio,
each of the third sensing holes includes a third opening on the surface of the porous plate, and
a total area of the third openings on the porous plate is larger than the total area of the second openings.

8. The measurement sensor of claim 1, wherein
the porous plate includes an insulating material and electrically insulates the probe electrodes in the plurality of sensing holes.

9. The measurement sensor of claim 1, further comprising:
a reference electrode on a side of the porous plate and configured to be electrically connected to the probe electrodes.

10. The measurement sensor of claim 9, further comprising:
a resistor between the reference electrode and the probe electrodes; and
a voltmeter between the reference electrode and the probe electrodes, and connected in parallel with the resistor.

11. The measurement sensor of claim 1, wherein
the probe electrode includes silicon, germanium, silicon-germanium, or carbon.

12. The measurement sensor of claim 1, wherein
the probe electrodes are under the plurality of sensing holes.

13. The measurement sensor of claim 12, wherein
the probe electrodes under the plurality of sensing holes are spaced apart from each other.

14. A measurement sensor comprising:
a case; and
a plurality of sensing ports on a surface of the case, wherein
each sensing port of the plurality of sensing ports includes,
a porous plate having a plurality of sensing holes, each sensing hole of the plurality of sensing holes including an opening on a surface of the porous plate; and
a probe electrode under the opening of each sensing hole of the plurality of sensing holes,
an aspect ratio of each sensing hole of the plurality of sensing holes is defined as a width of the opening to a depth from the opening to the probe electrode, and
the aspect ratios of the plurality of sensing holes differ from each other.

15. The measurement sensor of claim 14, wherein
the plurality of sensing ports are radially arranged on the surface of the case.

16. The measurement sensor of claim 14, wherein
each sensing port of the plurality of sensing ports further includes a reference electrode exposed through the surface of the case, each sensing port of the plurality of sensing ports being configured to be electrically connected to the probe electrode.

17. The measurement sensor of claim 16, wherein
each sensing port of the plurality of sensing ports further includes an insulating plate between the porous plate and the reference electrode, and
the insulating plate is formed such that the porous plate is spaced apart and electrically insulated from the reference electrode.

18. A substrate processing apparatus comprising:
a chamber defining a processing space;
a shower head in the chamber, the shower head having a plurality of shower head holes connected to the processing space;
a stage in the processing space; and
a measurement sensor on the stage facing the processing space, wherein
the measurement sensor includes,
a porous plate having a plurality of sensing holes, each sensing hole of the plurality of sensing holes including an opening on a surface of the porous plate; and
a probe electrode under the opening of each sensing hole of the plurality of sensing holes,
an aspect ratio of each sensing hole of the plurality of sensing holes is defined as a width of the opening to a depth from the opening to the probe electrode, and
the aspect ratios of the plurality of sensing holes differ from each other.

19. The measurement sensor of claim 18, wherein
the probe electrodes are exposed to the processing space by the plurality of sensing holes.

20. The measurement sensor of claim 18, wherein
the measurement sensor further includes a reference electrode exposed to the processing space, the measurement sensor being configured to be electrically connected to the probe electrode.
